(19) United States
(12) Patent Application Publication
(10) Pub. No.: US 2017/0096853 A1
(43) Pub. Date: Apr. 6, 2017

(54) Multisectional Blind and Solar Collector Combination Device

(71) Applicant: Timothy Eubanks, SR., Carson, CA (US)

(72) Inventor: Timothy Eubanks, SR., Carson, CA (US)

(21) Appl. No.: 14/874,003

(22) Filed: Oct. 2, 2015

(51) Int. Cl. E06B 9/322; H02S 40/38; E06B 9/24; H01L 31/042

(52) U.S. Cl. CPC E06B 9/322; H01L 31/042; H02S 40/38; E06B 9/24; E06B 2009/2476; E06B 2009/3222

(57) ABSTRACT

A multisectional blind and solar collector combination device for combined window covering and solar collection includes a housing with a back face that comprises a fixed solar panel. A power module is coupled to and positioned in the housing. The power module is operationally coupled to the fixed solar panel. A plurality of slats is positioned in a plurality of sections. The slats of each section are coupled to a respective horizontal support. The horizontal supports are coupled to a bottom of the housing in a tiered formation.

### BACKGROUND OF THE DISCLOSURE

### Field of the Disclosure

The disclosure relates to multisectional blind devices and more particularly pertains to a new multisectional blind device for combined window covering and solar collection.

SUMMARY OF THE DISCLOSURE

An embodiment of the disclosure meets the needs presented above by generally comprising a housing with a back face that comprises a fixed solar panel. A power module is coupled to and positioned in the housing. The power module is operationally coupled to the fixed solar panel. A plurality of slats is positioned in a plurality of sections. The slats of each section are coupled to a respective horizontal support. The horizontal supports are coupled to a bottom of the housing in a tiered formation.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF THE DRAWINGS

The disclosure will be better understood and objects other than those set forth above will become apparent when consideration is given to the following detailed description thereof. Such description makes reference to the annexed drawings wherein:

FIG. 1 is a front partial cut-away view of a multisectional blind and solar collector combination device according to an embodiment of the disclosure.

FIG. 2 is a side view of an embodiment of the disclosure.

FIG. 3 is a back view of an embodiment of the disclosure.

FIG. 4 is a front view of an embodiment of the disclosure.

FIG. 5 is a front view of an embodiment of the disclosure.

### DESCRIPTION OF THE PREFERRED EMBODIMENT

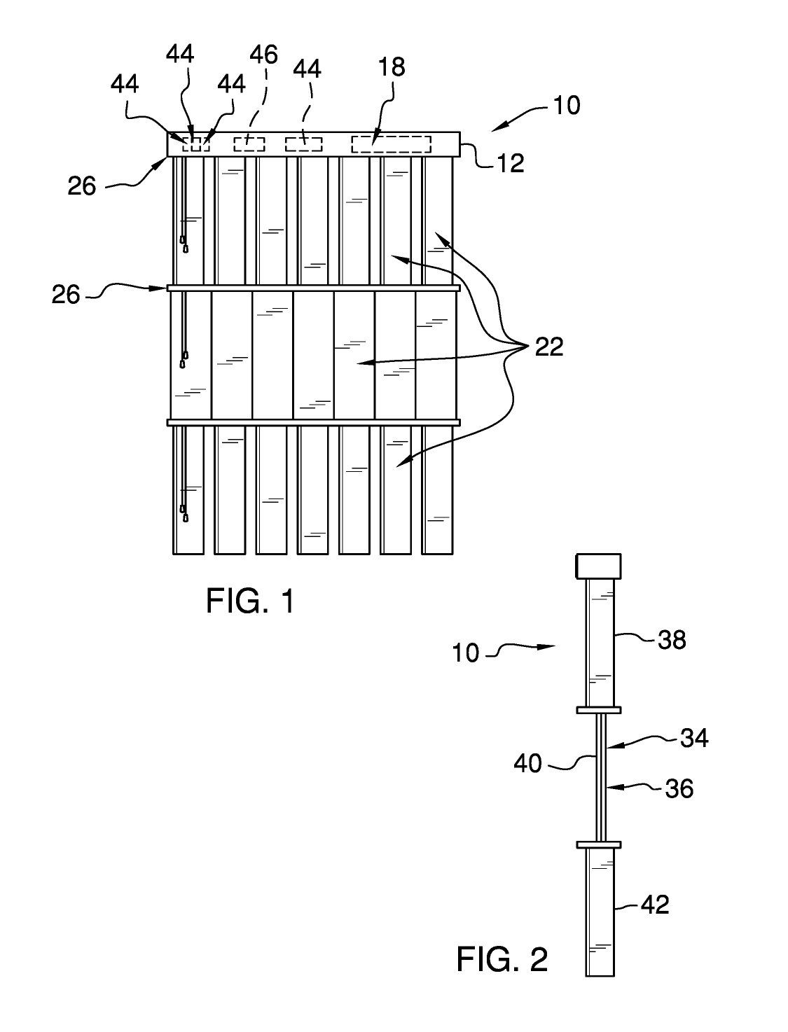

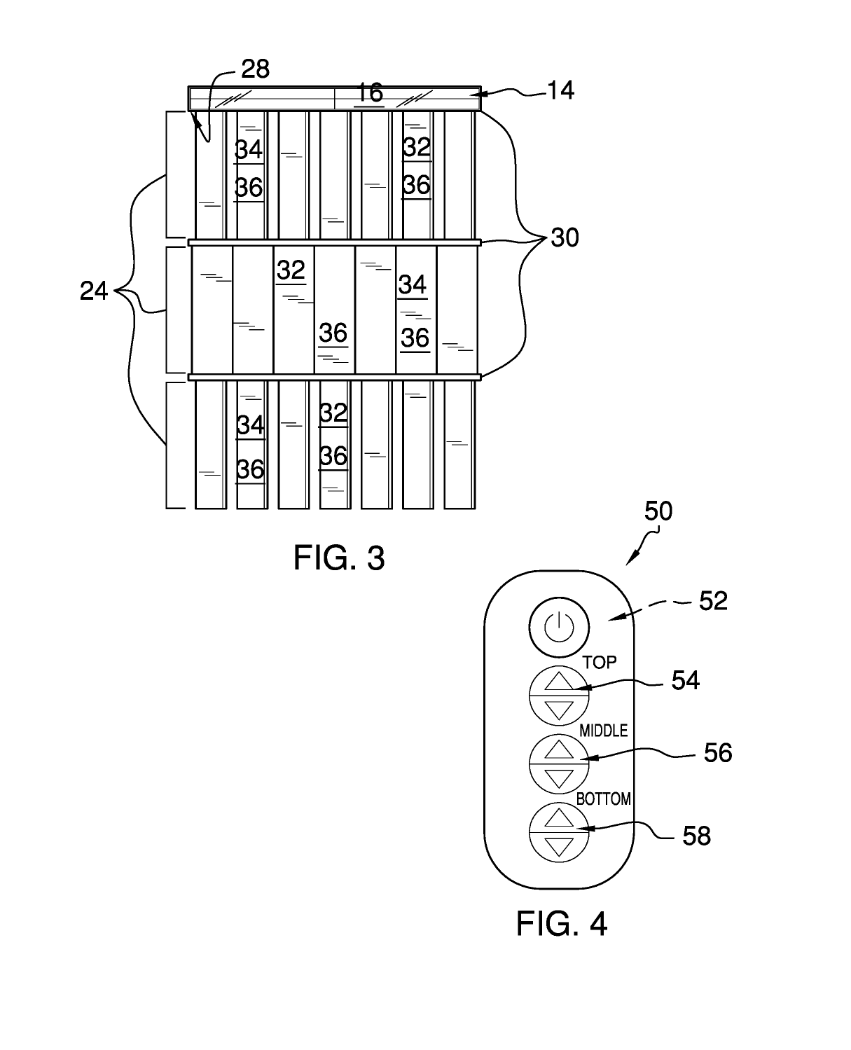

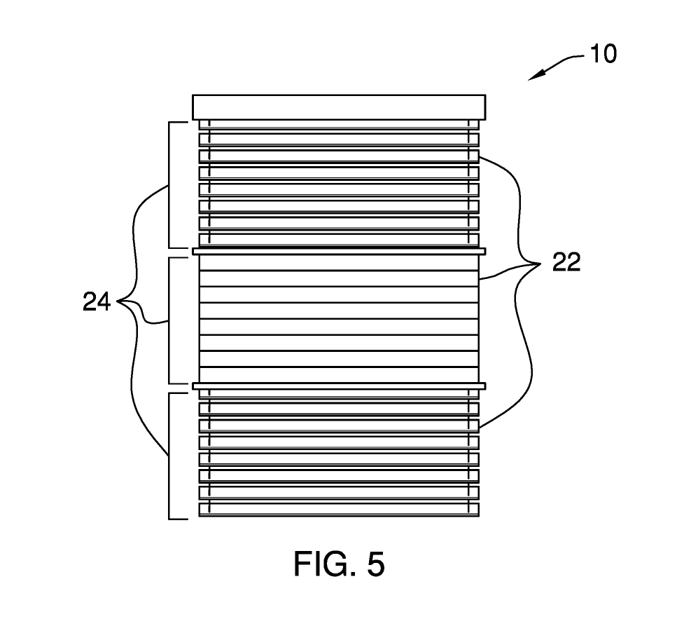

With reference now to the drawings, and in particular to FIGS. 1 through 5 thereof, a new multisectional blind device embodying the principles and concepts of an embodiment of the disclosure and generally designated by the reference numeral 10 will be described.

As best illustrated in FIGS. 1 through 5, the multisectional blind and solar collector combination device 10 generally comprises a housing 12 with a back face 14 that comprises a fixed solar panel 16. A power module 18 is coupled to and positioned in the housing 12. The power module 18 is operationally coupled to the fixed solar panel 16. The power module 18 comprises at least one rechargeable battery 20. A plurality of slats 22 is positioned in a plurality of sections 24. The slats 22 of each section 24 are coupled to a respective horizontal support 26. The horizontal supports 26 are coupled to a bottom 28 of the housing 12 in a tiered formation 30, such that each section 24 can be configured independently by the user with the slats 22 open, closed or intermediately positioned.

The slats 22 may comprise rotatable solar panels 32 that are operationally coupled to the power module 18. Alternatively, the slats 22 may have photovoltaic modules 34 coupled to a back side 36 of the slats 22. The photovoltaic modules 34 are operationally coupled to the power module 18. The plurality of sections 24 comprises two to four sections. Preferably, the plurality of sections 24 comprises a top section 38, a middle section 40, and a bottom section 42. The slats 22 may be positioned horizontally or vertically.

A plurality of motors 44 is coupled to and positioned in the housing 12. Each of the motors 44 is operationally coupled to the power module 18. One of each of the plurality of motors 44 is operationally coupled to a respective one of the plurality of sections 24. Preferably, the plurality of motors 44 comprises three motors. A controller 46 with a wireless receiver 48 is operationally coupled to the power module 18 and the motors 44. A remote control 50 with a wireless transmitter 52 is capable of signaling the controller 46. The remote control 50 has a top control 54 for the top section 38, a middle control 56 for the middle section 40, and a bottom control 58 for the bottom section 42.

In use, the fixed solar panel 16 is positioned on the housing 12 such that the fixed solar panel 16, upon exposure to light, will generate current that flows to and is stored by the power module 18. The user can configure each of the plurality of sections 24 individually with the slats 22 open, closed or intermediately positioned.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

1. A multisectional blind and solar collector combination device comprising:
a housing, said housing having a back face, said back face comprising a fixed solar panel;
a power module, said power module being coupled to and positioned in said housing, said power module being operationally coupled to said fixed solar panel; and
a plurality of slats, said slats being positioned in a plurality of sections, said slats of each said section being coupled to a respective horizontal support, said horizontal supports being coupled to a bottom of said housing in a tiered formation, each of said slats being positioned vertically.

2. The device of claim 1, further comprising:
a plurality of motors, each of said motors being coupled to and positioned in said housing, each of said motors being operationally coupled to said power module, one of each said motors being operationally coupled to a respective one of said plurality of sections;
a controller, said controller being operationally coupled to said power module and said motors, said controller having a wireless receiver; and
a remote control, said remote control having a wireless transmitter, said remote control being capable of signaling said controller, wherein each said motor is induced to position said respective one of said plurality of sections with said slats open, closed or intermediately positioned.

3. The device of claim 2, further including said plurality of sections comprising two to four sections.

4. The device of claim 3, further including said plurality of sections comprising a top section, a middle section, and a bottom section.

5. The device of claim 2, further including said plurality of motors comprising three motors.

6. The device of claim 4, further including said remote control having a top control for said top section, a middle control for said middle section, and a bottom control for said bottom section.

7. The device of claim 1, further including said power module comprising at least one rechargeable battery.

8. The device of claim 1, further including said slats comprising rotatable solar panels, said rotatable solar panels being operationally coupled to said power module.

9. The device of claim 1, further including said slats having photovoltaic modules coupled to a back side of said slats, said photovoltaic modules being operationally coupled to said power module.

10. The device of claim 1, further including said slats being positioned horizontally.

11. (canceled)

12. A multisectional blind and solar collector combination device comprising:
a housing, said housing having a back face, said back face comprising a fixed solar panel;
a power module, said power module being coupled to and positioned in said housing, said power module being operationally coupled to said fixed solar panel, said power module comprising at least one rechargeable battery;
a plurality of slats, said slats being positioned in a plurality of sections, said slats of each said section being coupled to a respective horizontal support, said horizontal supports being coupled to a bottom of said housing in a tiered formation, wherein each said section can be positioned independently by the user with said slats open, closed or intermediately positioned, said slats comprising rotatable solar panels, said rotatable solar panels being operationally coupled to said power module, said slats having photovoltaic modules coupled to a back side of said slats, said photovoltaic modules being operationally coupled to said power module, said plurality of sections comprising two to four sections, said plurality of sections comprising a top section, a middle section, and a bottom section, said slats being positioned horizontally, said slats being positioned vertically;
a plurality of motors, each of said motors being coupled to and positioned in said housing, each of said motors being operationally coupled to said power module, one of each said motors being operationally coupled to a respective one of said plurality of sections, said plurality of motors comprising three motors, wherein each said motor is enabled to rotate said slats positioned in said respective one of said plurality of sections;
a controller, said controller being operationally coupled to said power module and said motors, said controller having a wireless receiver;
a remote control, said remote control having a wireless transmitter, said remote control being capable of signaling said controller, wherein each said motor is induced to position said respective one of said plurality of sections with said slats open, closed or intermediately positioned, said remote control having a top control for said top section, a middle control for said middle section, and a bottom control for said bottom section; and
wherein said fixed solar panel is positioned on said housing such that said fixed solar panel upon exposure to light will generate current that flows to and is stored by said power module, and wherein the user can configure each of said plurality of sections individually with said slats being open, closed or intermediately positioned.
